(19) United States
(12) Patent Application Publication
(10) Pub. No.: US 2025/0081651 A1
(43) Pub. Date: Mar. 6, 2025

(54) IMAGE SENSING DEVICE INCLUDING SLOPED ISOLATION STRUCTURE

(71) Applicant: SK hynix Inc., Icheon-si (KR)

(72) Inventors: Jong Eun KIM, Icheon-si (KR); Kyung Do KIM, Icheon-si (KR); Hyung June YOON, Icheon-si (KR); Jae Hyung JANG, Icheon-si (KR); Hoon Moo CHOI, Icheon-si (KR)

(21) Appl. No.: 18/433,254

(22) Filed: Feb. 5, 2024

(30) Foreign Application Priority Data
Sep. 5, 2023 (KR) 10-2023-0117997

(51) Int. Cl. H01L 27/146

(52) U.S. Cl. CPC H10F 39/807; H10F 39/802

(57) ABSTRACT

An image sensing device includes a substrate extending in a first direction and a second direction and including a first surface and a second surface; a plurality of unit pixel regions supported by the substrate to generate signal carriers through conversion of incident light; a plurality of circuit structures arranged to be spaced apart from each other in the first direction to generate a current in the substrate and capture the signal carriers carried by the current; a first isolation structure disposed between adjacent unit pixel regions in the substrate and extending vertically in a depth direction of the substrate while extending in the second direction; and a plurality of second isolation structures located on two opposite sides of the plurality of circuit structures in the second direction within the substrate, and arranged to extend obliquely in a depth direction in the substrate while extending in the first direction.

### CROSS-REFERENCE TO RELATED APPLICATION

This patent document claims the priority and benefits of Korean patent application No. 10-2023-0117997, filed on Sep. 5, 2023, which is incorporated by reference in its entirety as part of the disclosure of this patent document.

### TECHNICAL FIELD

The technology and implementations disclosed in this patent document generally relate to an image sensing device including an isolation structure that extends obliquely in a depth direction of a substrate.

### BACKGROUND

An image sensor is a device for capturing optical images by converting light into electrical signals using a photosensitive semiconductor material which reacts to light. With the recent development of automotive, medical, computer and communication industries, the demand for high-performance image sensors is increasing in various fields such as smart phones, digital cameras, camcorders, personal communication systems (PCSs), game consoles, IoT (Internet of Things), robots, surveillance cameras, medical micro cameras, etc.

### SUMMARY

Various embodiments of the disclosed technology relate to an image sensing device capable of improving detection efficiency while reducing power consumption required for a sensing operation.

In an embodiment of the disclosed technology, an image sensing device may include a substrate structured to extend in a first direction and a second direction perpendicular to the first direction and configured to include a first surface and a second surface opposite to the first surface; a plurality of unit pixel regions supported by the substrate and configured to generate signal carriers through conversion of incident light; a plurality of circuit structures supported by the substrate and arranged to be spaced apart from each other in the first direction and configured to generate a current in the substrate and capture the signal carriers carried by the current; a first isolation structure disposed between adjacent unit pixel regions of the plurality of unit pixel regions in the substrate, and configured to extend vertically in a depth direction of the substrate while extending in the second direction; and a plurality of second isolation structures located on two opposite sides of the plurality of circuit structures in the second direction within the substrate, and arranged to extend obliquely in a depth direction in the substrate while extending in the first direction.

In another embodiment of the disclosed technology, an image sensing device may include a substrate extending in a first direction and a second direction perpendicular to the first direction and including a first surface and a second surface opposite to the first surface; a plurality of circuit structures arranged to be spaced apart from each other in the first direction on the second surface of the substrate, and configured to generate a current in the substrate and capture the signal carriers moving by the current; first pixel transistors disposed at one side of the plurality of circuit structures in the second direction on the second surface of the substrate; second pixel transistors disposed at opposite sides of the plurality of circuit structures in the second direction on the second surface of the substrate; a first isolation structure disposed obliquely in a depth direction of the substrate within the substrate, and configured to cover the first pixel transistors to prevent incident light received through the first surface from flowing into the first pixel transistors; and a second isolation structure disposed obliquely in the depth direction of the substrate within the substrate, and configured to cover the second pixel transistors to prevent incident light received through the first surface from flowing into the second pixel transistors.

In another embodiment of the disclosed technology, an image sensing device may include a substrate formed to include a first surface and a second surface facing or opposite to the first surface, and configured to generate signal carriers through conversion of incident light; a plurality of taps arranged to be spaced apart from each other in a first direction, and configured to generate a hole current in the substrate and capture the signal carriers moving by the hole current; a first isolation structure disposed between adjacent unit pixels in the substrate, and configured to extend vertically in a depth direction of the substrate while extending in a second direction perpendicular to the first direction; and a plurality of second isolation structures located on both sides of the plurality of taps in the second direction within the substrate, and configured to extend obliquely in a depth direction of the substrate while extending in the first direction.

In another embodiment of the disclosed technology, an image sensing device may include a substrate formed to include a first surface and a second surface facing or opposite to the first surface; a plurality of taps arranged to be spaced apart from each other in a first direction on a second surface of the substrate, and configured to generate a hole current in the substrate and capture signal carriers moving by the hole current; first pixel transistors disposed at one side of the plurality of taps in a second direction perpendicular to the first direction on a second surface of the substrate; second pixel transistors disposed at opposite sides of the plurality of taps in the second direction on the second surface of the substrate; a first isolation structure disposed to be inclined in a depth direction of the substrate within the substrate, and configured to cover the first pixel transistors to prevent incident light received through the first surface from flowing into the first pixel transistors; and a second isolation structure disposed to be inclined in the depth direction of the substrate within the substrate, and configured to cover the second pixel transistors to prevent incident light received through the first surface from flowing into the second pixel transistors.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a circuit diagram illustrating an example of a unit pixel shown in FIG. 1 based on some implementations of the disclosed technology.

FIG. 3 is a plan view illustrating an example of a pixel array shown in FIG. 1 based on some implementations of the disclosed technology.

FIG. 4 is a cross-sectional view illustrating an example of a pixel array taken along the line X-X′ shown in FIG. 3 based on some implementations of the disclosed technology.

FIG. 5 is a cross-sectional view illustrating an example of a pixel array taken along the line Y1-Y1′ shown in FIG. 3 based on some implementations of the disclosed technology.

FIG. 6 is a cross-sectional view illustrating an example of a pixel array taken along the line Y2-Y2′ shown in FIG. 3 based on some implementations of the disclosed technology.

FIGS. 7A to 7F are cross-sectional views illustrating examples of a method for forming isolation structures shown in FIG. 5 based on some implementations of the disclosed technology.

FIGS. 8A to 8C are cross-sectional views illustrating examples of a pixel array taken along the line Y1-Y1′ shown in FIG. 3 based on some implementations of the disclosed technology.

FIG. 9 is a plan view illustrating an example of a pixel array shown in FIG. 1 based on some implementations of the disclosed technology.

### DETAILED DESCRIPTION

This patent document provides implementations and examples of an image sensing device including an isolation structure that extends obliquely in a depth direction of a substrate, thereby substantially addressing one or more technical or engineering issues in some other image sensing devices. Some implementations of the disclosed technology suggest examples of an image sensing device that can improve detection efficiency while reducing power consumption required for a sensing operation. The disclosed technology can be implemented in some embodiments to provide various implementations of the image sensing device that can improve detection efficiency while reducing power consumption required for a sensing operation.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

In order to acquire a three-dimensional (3D) image using the image sensor, color information of the 3D image and the distance (or depth) between a target object and the image sensor are needed.

Methods for measuring depth information regarding a target object using one or more image sensors include a triangulation method and a Time of Flight (TOF) method. The TOF method is being widely used because of its high processing speed and cost advantages. The TOF method measures a distance using emitted light and reflected light and is classified into two different types, a direct method and an indirect method, depending on whether a round-trip time or a phase difference is used to determine the distance between the image sensor and the target object. The direct method may calculate a round trip time using emitted light and reflected light and measure the distance (i.e., depth) to the target object using the calculated round trip time. The indirect method may measure the distance to the target object using a phase difference. The direct method is suitable for long-distance measurement and thus is widely used in automobiles. The indirect method is suitable for short-distance measurement and thus is widely used in various higher-speed devices designed to operate at a higher speed, for example, game consoles, mobile cameras, or others. The indirect method has several advantages over the direct type TOF systems, including having simpler circuitry, low memory requirement, and a relatively low cost.

A current-assisted photonic demodulator (CAPD) structure can be used as a pixel type of indirect TOF sensors. The CAPD structure can detect electrons that have been generated in a substrate using a hole current acquired by applying a voltage to the substrate. The CAPD structure has an excellent efficiency in detecting electrons and can detect electrons formed at a deep depth.

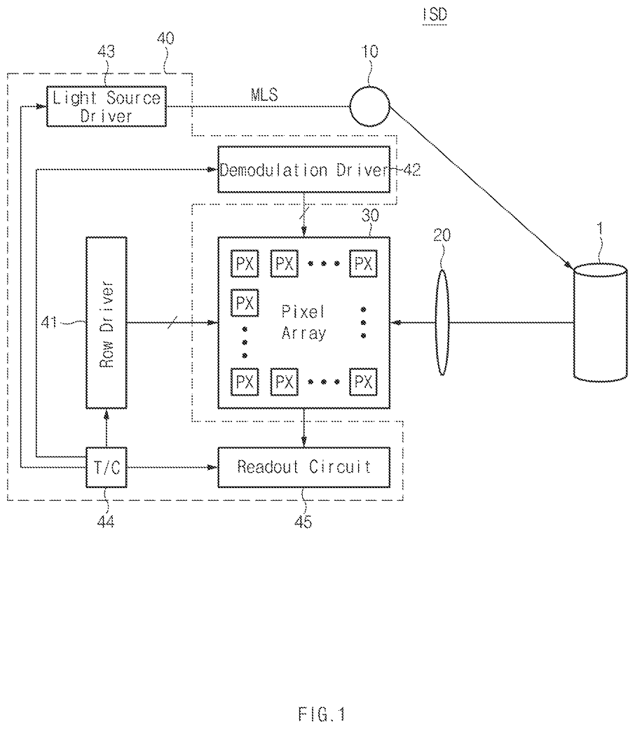

FIG. 1 is a block diagram illustrating an example of an image sensing device ISD based on some implementations of the disclosed technology.

Referring to FIG. 1, the image sensing device ISD may measure the distance to a target object 1 using the indirect Time of Flight (TOF) principle. The TOF method may be mainly classified into a direct TOF method and an indirect TOF method. The indirect TOF method may emit modulated light to the target object 1, may sense light reflected from the target object 1, may calculate a phase difference between the modulated light and the reflected light, and may thus indirectly measure the distance between the image sensing device ISD and the target object 1.

The image sensing device ISD may include a light source 10, a lens module 20, a pixel array 30, and a control block 40.

The light source 10 may emit light to a target object 1 upon receiving a modulated light signal (MLS) from the control block 40. The light source 10 may be a laser diode (LD) or a light emitting diode (LED) for emitting light (e.g., near infrared (NIR) light, infrared (IR) light or visible light) having a specific wavelength band, or may be any one of a Near Infrared Laser (NIR), a point light source, a monochromatic light source combined with a white lamp or a monochromator, and a combination of other laser sources. For example, the light source 10 may emit infrared light having a wavelength of 800 nm to 1000 nm. Although FIG. 1 shows only one light source 10 for convenience of description, the scope or spirit of the disclosed technology is not limited thereto, and a plurality of light sources may also be arranged in the vicinity of the lens module 20.

The lens module 20 may collect light reflected from the target object 1, and may allow the collected light to be focused onto pixels (PXs) of the pixel array 30. For example, the lens module 20 may include a focusing lens having a surface formed of glass or plastic or another cylindrical optical element having a surface formed of glass or plastic. The lens module 20 may include a plurality of lenses that is arranged to be focused upon an optical axis.

The pixel array 30 may include unit pixels (PXs) consecutively arranged in a two-dimensional (2D) matrix structure in which unit pixels are arranged in a column direction and a row direction perpendicular to the column direction. The unit pixels (PXs) may be formed over a semiconductor substrate. Each unit pixel (PX) may convert incident light received through the lens module 20 into an electrical signal corresponding to the amount of incident light, and may thus output a pixel signal using the electrical signal. In this case, the pixel signal may be a signal indicating the distance to the target object 1. For example, each unit pixel (PX) may be a Current-Assisted Photonic Demodulator (CAPD) pixel for capturing photocharges generated in a semiconductor substrate by incident light using a difference between potential levels of an electric field. The pixel array 30 may include pixel isolations (also referred to as ‘pixel isolation units’) formed in a substrate. Some of the pixel isolations may be formed to be inclined in a vertical direction. The specific structure of these pixel isolations will be described later.

The control block 40 may emit light to the target object 1 by controlling the light source 10, may process each pixel signal corresponding to light reflected from the target object 1 by driving unit pixels (PXs) of the pixel array 30, and may measure the distance to the surface of the target object 1 using the processed result.

The control block 40 may include a row driver 41, a demodulation driver 42, a light source driver 43, a timing controller (T/C) 44, and a readout circuit 45.

The row driver 41 and the demodulation driver 42 may be generically called a control circuit for convenience of description.

The control circuit may drive unit pixels (PXs) of the pixel array 30 in response to a timing signal generated from the timing controller 44.

The control circuit may generate a control signal capable of selecting and controlling at least one row line from among the plurality of row lines. The control signal may include a demodulation control signal for generating a pixel current in the substrate, a reset signal for controlling a reset transistor, a transmission (Tx) signal for controlling transmission of photocharges accumulated in a detection node, a floating diffusion (FD) signal for providing additional electrostatic capacity at a high illuminance level, a selection signal for controlling a selection transistor, and the like. The pixel current may refer to a current for moving photocharges generated by the substrate to the detection node.

In this case, the row driver 41 may generate a reset signal, a transmission (Tx) signal, a floating diffusion (FD) signal, and a selection signal, and the demodulation driver 42 may generate a demodulation control signal. Although the row driver 41 and the demodulation driver 42 based on some implementations of the disclosed technology are configured independently of each other, the row driver 41 and the demodulation driver 42 based on some other implementations may be implemented as one constituent element that can be disposed at one side of the pixel array 30 as needed.

The light source driver 43 may generate a modulated light signal MLS capable of driving the light source 10 in response to a control signal from the timing controller 44. The modulated light signal MLS may be a signal that is modulated by a predetermined frequency.

The timing controller 44 may generate a timing signal to control the row driver 41, the demodulation driver 42, the light source driver 43, and the readout circuit 45.

The readout circuit 45 may process pixel signals received from the pixel array 30 under control of the timing controller 44, and may thus generate pixel data formed in a digital signal shape. To this end, the readout circuit 45 may include a correlated double sampler (CDS) circuit for performing correlated double sampling (CDS) on the pixel signals generated from the pixel array 30. In addition, the readout circuit 45 may include an analog-to-digital converter (ADC) for converting output signals of the CDS circuit into digital signals. In addition, the readout circuit 45 may include a buffer circuit that temporarily stores pixel data generated from the analog-to-digital converter (ADC) and outputs the pixel data under control of the timing controller 44. In the meantime, the pixel array 30 includes Current-Assisted Photonic Demodulator (CAPD) pixels. Therefore, two column lines for transmitting the pixel signal may be assigned to each column of the pixel array 30, and structures for processing the pixel signal generated from each column line may be configured to correspond to the respective column lines.

The light source 10 may emit light (i.e., modulated light) modulated by a predetermined frequency to a scene captured by the image sensing device ISD. The image sensing device ISD may sense modulated light (i.e., incident light) reflected from the target objects 1 included in the scene, and may thus generate depth information for each unit pixel (PX). A time delay based on the distance between the image sensing device ISD and each target object 1 may occur between the modulated light and the incident light. The time delay may be denoted by a phase difference between the signal generated by the image sensing device ISD and the light modulation signal MLS controlling the light source 10. An image processor (not shown) may calculate a phase difference generated in the output signal of the image sensing device ISD, and may thus generate a depth image including depth information for each unit pixel (PX).

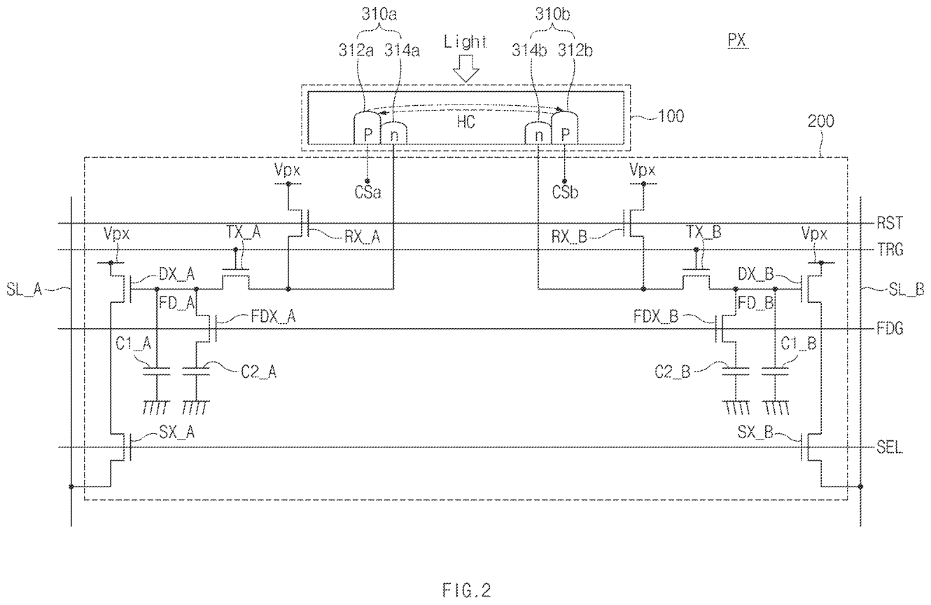

FIG. 2 is a circuit diagram illustrating an example of a unit pixel (PX) shown in FIG. 1 based on some implementations of the disclosed technology.

Referring to FIG. 2, the unit pixel (PX) may be one of the unit pixels (PXs) shown in FIG. 1.

The unit pixel (PX) may include a photoelectric conversion region 100 and a circuit region 200.

The photoelectric conversion region 100 may include a first signal extractor 310a and a second signal extractor 310b that are formed in a semiconductor substrate. The first signal extractor 110a may include a first control node 312a and a first detection node 314a, and the second signal extractor 310b may include a second control node 312b and a second detection node 314b.

The first control node 312a may receive a first demodulation control signal (CSa) from the demodulation driver 42, and the second control node 312b may receive the second demodulation control signal (CSb) from the demodulation driver 42. An electric potential difference between the first demodulation control signal (CSa) and the second demodulation control signal (CSb) may generate an electrical current, which may include, a hole current (HC) carrying positive charges such as holes in the direction of the current and which may also be formed by negative charges such as electrons moving in the opposite direction of the current. The existence of the electrical current (e.g., hole current (HC)) may control the flow of signal carriers generated within the substrate by incident light. For example, when the voltage of the first demodulation control signal (CSa) is higher than the voltage of the second demodulation control signal (CSb), the current (e.g., hole current (HC)) may flow from the first control node 312a to the second control node 112b. Conversely, when the voltage of the first demodulation control signal (CSa) is lower than the voltage of the second demodulation control signal (CSb), the current (e.g., a hole current (HC)) may flow from the second control node 312b to the first control node 312a.

Each of the first and second detection nodes (314a, 314b) may capture signal carriers moving according to flow of the current, e.g., a hole current (HC), so that the signal carriers are accumulated.

The operation of capturing signal carriers in the photoelectric conversion region 100 may be performed over a first period and a second period following the first period.

In the first period, light incident upon the unit pixel (PX) may be subjected to photoelectric conversion, such that a pair of an electron and a hole may be generated in the substrate according to the intensity of incident light. In some implementations, electrons generated in response to the intensity of incident light may refer to photocharges. In this case, the demodulation driver 42 may output a first demodulation control signal (CSa) to the first control node 312a, and may output a second demodulation control signal (CSb) to the second control node 312b. In the first period, the first demodulation control signal (CSa) may have a higher voltage than the second demodulation control signal (CSb). In this case, the voltage of the first demodulation control signal (CSa) may be defined as an active voltage (also called an activation voltage), and the voltage of the second demodulation control signal (CSb) may be defined as an inactive voltage (also called a deactivation voltage). For example, the voltage of the first demodulation control signal (CSa) may be set to 1.2 V, and the voltage of the second demodulation control signal (CSb) may be zero volts (0V).

An electric field may be created between the first control node 312a and the second control node 312b due to a voltage difference between the first demodulation control signal (CSa) and the second demodulation control signal (CSb), and the current (e.g., hole current (HC)) may flow from the first control node 312a to the second control node 312b. That is, holes in the substrate may move toward the second control node 312b, and electrons in the substrate may move toward the first control node 312a.

Electrons moving toward the first control node 312a may be captured by the first detection node 314a adjacent to the first control node 312a. Therefore, electrons in the substrate may be used as signal carriers for detecting the amount of incident light.

In the second period subsequent to the first period, light incident upon the pixel (PX) may be processed by photoelectric conversion, and a pair of an electron and a hole may be generated in the substrate according to the amount of incident light (e.g., the intensity of incident light). In this case, the demodulation driver 42 may output the first demodulation control signal (CSa) to the first control node 312a, and may output the second demodulation control signal (CSb) to the second control node 312b. Here, the first demodulation control signal (CSa) may have a lower voltage than the second demodulation control signal (CSb). In this case, the voltage of the first demodulation control signal (CSa) may be referred to as an inactive voltage (e.g., deactivation voltage), and the voltage of the second demodulation control signal (CSb) may be referred to as an active voltage (e.g., activation voltage). For example, the voltage of the first demodulation control signal (CSa) may be zero volts (0V), and the voltage of the second demodulation control signal (CSb) may be set to 1.2 V.

An electric field may be created between the first control node 312a and the second control node 312b due to a voltage difference between the first demodulation control signal (CSa) and the second demodulation control signal (CSb), and the current (e.g., hole current (HC)) may flow from the second control node 312b to the first control node 312a. That is, holes in the substrate may move toward the first control node 312a, and electrons in the substrate may move toward the second control node 312b.

Electrons moving toward the second control node 312b may be captured by the second detection node 314b adjacent to the second control node 312b. Therefore, electrons in the substrate may be used as signal carriers for detecting the amount of incident light.

In some implementations, the first period may follow the second period.

The circuit region 200 may be located at one side of the photoelectric conversion region 100. The circuit region 200 may include a plurality of elements (i.e., pixel transistors) (DX_A, SX_A, FDX_A, TX_A, RX_A, DX_B, SX_B, FDX_B, TX_B, RX_B) for processing photocharges captured by the first and second detection nodes 314a and 314b and converting the photocharges into electrical signals, and may include interconnect lines (e.g., wirings) for electrical connection between the pixel transistors (DX_A, SX_A, FDX_A, TX_A, RX_A, DX_B, SX_B, FDX_B, TX_B, RX_B). Control signals (RST, TRG, FDG, SEL) applied to the circuit region 200 may be provided from the row driver 41. In addition, a pixel voltage (Vpx) may be a power-supply voltage (VDD).

Circuitry for processing photocharges captured by the first detection node 314a will hereinafter be described with reference to the attached drawings. The circuit region 200 may include a reset transistor RX_A, a transfer transistor TX_A, a first capacitor C1_A, a second capacitor C2_A, a floating diffusion (FD) transistor FDX_A, a drive transistor DX_A, and a selection transistor SX_A.

The reset transistor RX_A may be activated to enter an active state in response to a logic high level of the reset signal RST supplied to a gate electrode thereof, such that potential of the floating diffusion node FD_A and potential of the first detection node 314a may be reset to a level of the pixel voltage (Vpx). In addition, when the reset transistor RX_A is activated (e.g., active state), the transfer transistor TX_A can also be activated (e.g., active state) to reset the floating diffusion node FD_A.

The transfer transistor TX_A may be activated (e.g., active state) in response to a logic high level of the transfer signal TRG applied to a gate electrode of the transfer transistor TX_A, such that charges accumulated in the first detection node 314a can be transmitted to the floating diffusion node FD_A.

The first capacitor C1_A may be coupled to the floating diffusion node FD_A, such that the first capacitor C1_A can provide predefined electrostatic capacity. The second capacitor C2_A may be selectively coupled to the floating diffusion node FD_A according to operations of the floating diffusion transistor FDX_A, such that the second capacitor C2_A can provide additional predefined electrostatic capacity.

Each of the first capacitor C1_A and the second capacitor C2_A may include, for example, at least one of a Metal-Insulator-Metal (MIM) capacitor, a Metal-Insulator-Polysilicon (MIP) capacitor, a Metal-Oxide-Semiconductor (MOS) capacitor, or a junction capacitor.

The floating diffusion transistor FDX_A may be activated (e.g., active state) in response to a logic high level of the floating diffusion signal FDG applied to a gate electrode of the floating diffusion transistor FDX_A, such that the floating diffusion transistor FDX_A may couple the second capacitor C2_A to the floating diffusion node FD_A.

For example, the row driver 41 may activate the floating diffusion transistor FDX_A when the amount of incident light corresponds to a relatively high illuminance condition, such that the floating diffusion transistor FDX_A enters the active state and the floating diffusion node FD_A can be coupled to the second capacitor C2_A. As a result, when the amount of incident light corresponds to a high illuminance level, the floating diffusion node FD_A can accumulate much more photocharges therein, thereby securing a high dynamic range (HDR).

On the other hand, when the amount of incident light corresponds to a relatively low illuminance level, the row driver 41 may control the floating diffusion transistor FDX_A to be turned off (or to be deactivated), such that the floating diffusion node FD_A can be isolated from the second capacitor C2_A.

In some other implementations, the floating diffusion transistor FDX_A and the second capacitor C2_A may be omitted as necessary.

A drain electrode of the drive transistor DX_A is coupled to the pixel voltage (Vpx) and a source electrode of the drive transistor DX_A is coupled to a vertical signal line SL_A through the selection transistor SX_A. Since the drive transistor DX_A is connected to the floating diffusion node (FD_A) through a gate electrode thereof, the drive transistor DX_A may operate as a source follower transistor that outputs a current (e.g., a pixel signal) having a predetermined magnitude corresponding to the electric potential of the floating diffusion node FD_A.

The selection transistor SX_A may be activated (e.g., active state) in response to a logic high level of the selection signal SEL applied to a gate electrode of the selection transistor SX_A, such that the pixel signal generated from the drive transistor DX_A can be output to the vertical signal line SL_A.

In order to process photocharges captured by the second detection node 314b, the circuit region 200 may include a reset transistor RX_B, a transfer transistor TX_B, a first capacitor C1_B, a second capacitor C2_B, a floating diffusion transistor FDX_B, a drive transistor DX_B, and a selection transistor SX_B. The circuitry for processing photocharges captured by the second detection node 314b may have operation timings different from operation timings of other circuitry for processing photocharges captured by the first detection node 314a. However, the circuitry for processing photocharges captured by the second detection node 314b may be substantially identical in structure and operation scheme to other circuitry for processing photocharges captured by the first detection node 314a.

The pixel signal transferred from the circuit region 200 to the vertical signal line SL_A and the pixel signal transferred from the circuit region 200 to the vertical signal line SL_B may be subjected to noise cancellation and analog-to-digital conversion (ADC) processing, such that each of the pixel signals can be converted into image data.

FIG. 2 illustrates each of the reset signal (RST), the transfer signal (TRG), the floating diffusion signal (FDG), and the selection signal (SEL) as being applied to the circuit region 200 through one signal line, but each of the reset signal (RST), the transfer signal (TRG), the floating diffusion signal (FDG), and the selection signal (SEL) may be applied to the circuit region 200 through a plurality of signal lines (e.g., two signal lines) so that the circuitry for processing photocharges captured by the first detection node 314a and the elements for processing photocharges captured by the second detection node 314b can operate at different timings.

An image processor (not shown) may determine a phase difference by calculating image data acquired from the photocharges captured by the first detection node 314a and image data acquired from the photocharges captured by the second detection node 314b. The image processor may determine depth information indicating a distance to the target object 1 from a phase difference corresponding to each pixel. The image processor may generate a depth image including depth information corresponding to each pixel based on the calculated depth information.

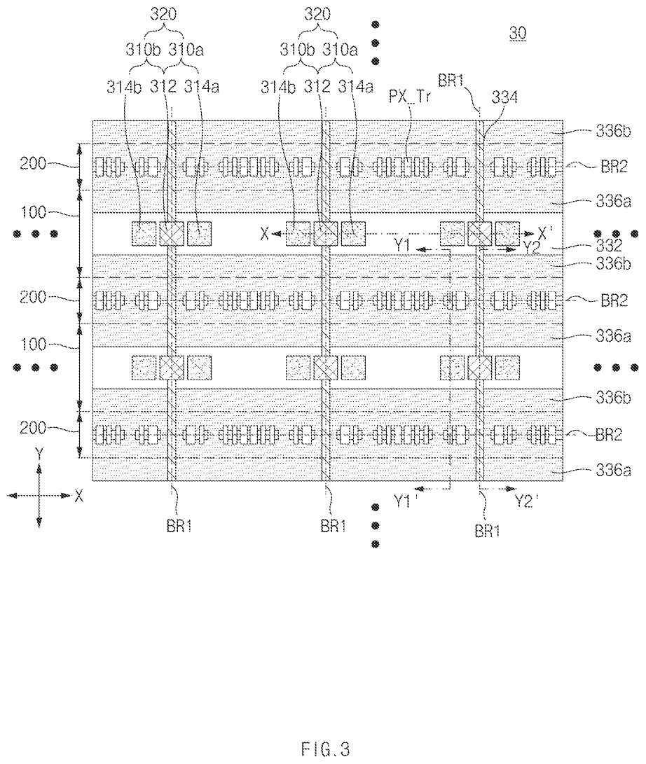

FIG. 3 is a plan view illustrating an example of the pixel array shown in FIG. 1 based on some implementations of the disclosed technology.

Referring to FIG. 3, the pixel array 30 may include a plurality of photoelectric conversion regions 100, and a plurality of circuit regions 200, each of which is located at one side of each photoelectric conversion region 100. For example, the pixel array 30 may include a structure in which the photoelectric conversion regions 100 and the circuit regions 200 form a pair and are consecutively arranged in a second direction (e.g., Y-axis direction).

Each photoelectric conversion region 100 may include a plurality of circuit structures 320, referred to herein as “taps,” which are arranged to be spaced apart from each other by a predetermined distance in a first direction (e.g., X-axis direction). Each circuit structure or tap 320 may include, as shown by the illustrated example in FIG. 3, not only a control node 312 formed of an electrically conductive material, but also a first detection node 314a (electrically conductive) and a second detection node 314b (electrically conductive) located at both sides of the control node 312 in the first direction.

Each circuit structure or tap 320 may be located to overlap a pixel boundary region BR1 between unit pixels. For example, in each circuit structure or tap 320, the center of the control node 312 may be located in the pixel boundary region BR1 to vertically overlap the isolation structure 334 extending in the second direction. In addition, both ends of the control node 312 may be disposed in unit pixels located at both sides of the corresponding pixel boundary region BR1, respectively. For example, one control node 312 may be formed across two adjacent unit pixels. The first detection node 314a and the second detection node 314b may be disposed in the unit pixels located at two opposite sides of the control node 312, respectively.

In some implementations, each unit pixel region may represent a region defined by the pixel boundary regions (BR1, BR2). For example, the region defined by two adjacent pixel boundary regions BR1 and two adjacent pixel boundary regions BR2 may be used as a unit pixel region.

Each tap 320 shown in FIG. 3 may include the first signal extractor 310a and the second signal extractor 310b shown in FIG. 2. For example, as shown in FIG. 3, one end of the control node 312 and the detection node 314a adjacent thereto may be used as the first signal extractor 310a, and the other end (e.g., an opposite end) opposite to the one end of the control node 312 and the detection node 314b adjacent thereto may be used as the second signal extractor 310b.

Each circuit region 200 may be disposed in the pixel boundary region BR2, and may include pixel transistors (PX_Tr). The pixel transistors (PX_Tr) may include the transistors (DX_A, SX_A, FDX_A, TX_A, RX_A, DX_B, SX_B, FDX_B, TX_B, RX_B) shown in FIG. 2. The pixel transistors (PX_Tr) may be formed to be linearly arranged in the first direction.

The pixel array 30 may include isolation structures (322, 334, 336a, 336b) formed in the semiconductor substrate.

The isolation structures 332 may be disposed between the control nodes 312, the detection nodes (314a, 314b), and the pixel transistors (PX_Tr) to electrically isolate the corresponding material layers and structures from each other. The isolation structure 332 may include a trench-shaped isolation structure formed such that an insulation material is buried in a trench formed by etching a second surface of the semiconductor substrate. For example, the isolation structure 332 may include a shallow trench isolation (STI) structure.

Each of the isolation structures 334 may be disposed between adjacent unit pixels in the first direction within the semiconductor substrate. For example, the pixel isolation structures 334 may be located in the pixel boundary region BR1. The isolation structure 334 may extend across the photoelectric conversion region 100 and the circuit region 200 in the second direction when viewed in a plane. The isolation structure 334 may extend entirely across the pixel array 30 in the second direction.

The isolation structures (336a, 336b) may be located across the photoelectric conversion region 100 and the circuit region 200 at both sides of the tap 320. The isolation structures (336a, 336b) may extend entirely across the pixel array 30 in the first direction when viewed in a plane. Further, the isolation structures (336a, 336b) may be formed to extend from the photoelectric conversion region 100 to the pixel boundary region BR2 at both sides of the taps 320 when viewed in a plane.

The isolation structures (334, 336a, 336b) may include a trench-shaped isolation structure such that an insulation material is buried in a trench formed by etching a substrate. For example, the isolation structures (334, 336a, 336b) may include a Deep Trench Isolation (DTI) structure. Alternatively, the isolation structures (334, 336a, 336b) may include a junction isolation structure in which impurities (e.g., P-type impurities) are implanted into the semiconductor substrate.

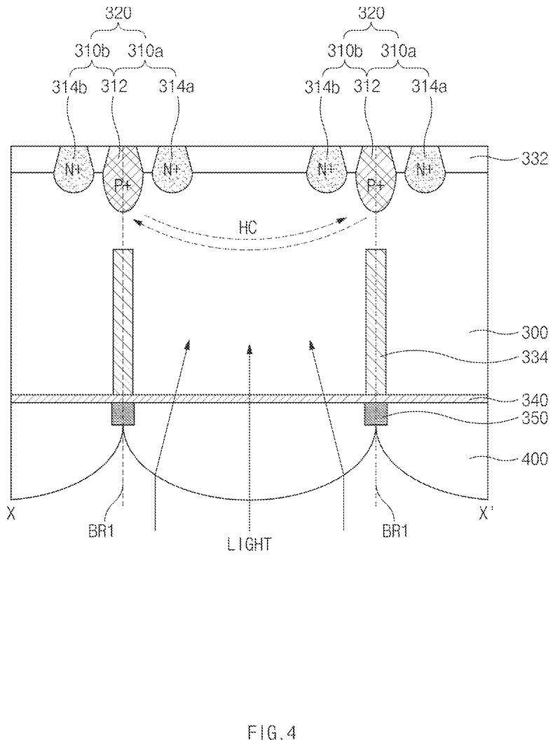

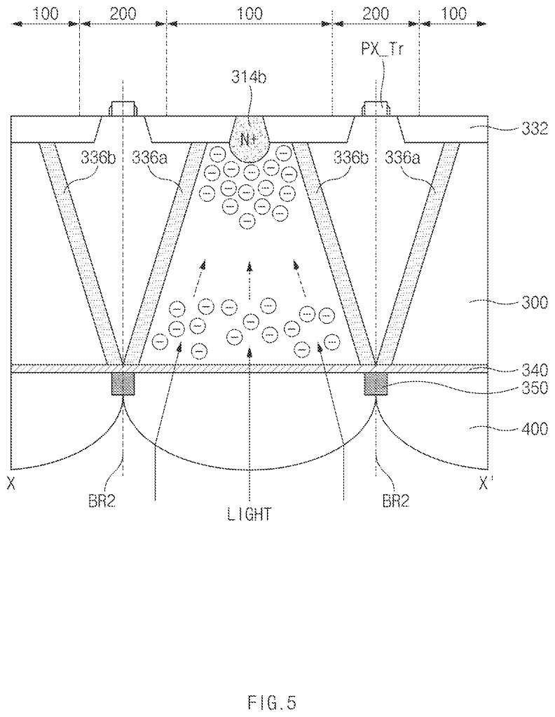

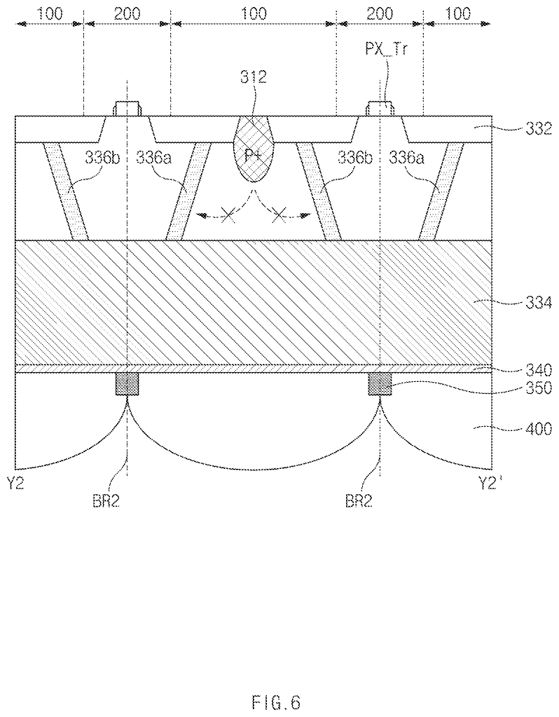

FIG. 4 is a cross-sectional view illustrating an example of the pixel array taken along the line X-X′ shown in FIG. 3 based on some implementations of the disclosed technology. FIG. 5 is a cross-sectional view illustrating an example of the pixel array taken along the line Y1-Y1′ shown in FIG. 3 based on some implementations of the disclosed technology. FIG. 6 is a cross-sectional view illustrating an example of the pixel array taken along the line Y2-Y2′ shown in FIG. 3 based on some implementations of the disclosed technology.

Referring to FIGS. 4 to 6, the semiconductor substrate 300 may include a first surface and a second surface facing or opposite to the first surface. The first surface may be a light reception surface upon which light is incident from the outside. The semiconductor substrate 300 may include an epitaxial silicon substrate.

The control node 312, the detection nodes (314a, 314b), and the pixel transistor (PX_Tr) may be located on a second surface of the semiconductor substrate 300, and may be formed in a region (e.g., active region) defined by the isolation structure 332 on the second surface. For example, the control node 312, the detection nodes (314a, 314b), and the pixel transistor (PX_Tr) may be isolated from each other by the isolation structure 332.

The control node 312 may be disposed to overlap the isolation structure 334 in the vertical direction. The detection nodes (314a, 314b) may be located at both sides of the control node 312 in the first direction, respectively. The pixel transistor (PX_Tr) may be located at both sides of the control node 312 and each of the detection nodes (314a, 314b) in the second direction.

The control node 312 may include impurities of a second type (e.g., P type), and each of the detection nodes (314a, 314b) may include impurities of a first type (e.g., N type) opposite to the second type (i.e., P type). Each of the control node 312 and the detection nodes (314a, 314b) may extend deeper than the region defined by the isolation structure 332. In some implementations, each of the control node 312 and the detection nodes (314a, 314b) may be formed with a uniform doping concentration. In other implementations, the control node 312 and the detection nodes (314a, 314b) can also be formed as a stacked structure in which the regions having different doping concentrations are stacked. For example, the control node 312 may be formed by stacking a P⁻ region having a relatively low doping concentration and a P⁺ region having a relatively high doping concentration. In this case, the P⁻ region may be formed to be deeper than the P⁺ region. Each of the detection nodes (314a, 314b) may be formed by stacking the N⁻ region and the N⁺ region, but the N-region may be formed to be deeper than the N⁺ region.

The isolation structure 332 may include a shallow trench isolation (STI) structure formed such that an insulation material is buried in a trench formed by etching the second surface of the semiconductor substrate 300 to a predetermined depth. The isolation structure 332 may define an active region in which the control node 312 and the detection nodes (314a, 314b) are formed, and may also define an active region in which the pixel transistor (PX_Tr) is formed.

The isolation structure 334 may extend perpendicular to the first and second directions in a depth direction of the semiconductor substrate 300. For example, the isolation structure 334 may be a vertical isolation structure that extends in a vertical direction from the first surface of the semiconductor substrate 300 toward the second surface of the semiconductor substrate 300 by a predetermined depth. The isolation structure 334 may be formed to overlap the center of the control node 312 while being spaced apart from the control node 312 by a predetermined distance.

The isolation structure 334 may include a trench-shaped isolation structure formed such that an insulation material is buried in a trench formed by etching the semiconductor substrate 300 in the vertical direction. For example, the isolation structure 334 may include a back deep trench isolation (BDTI) structure formed such that an insulation material is buried in a trench etched from the first surface to the second surface of the semiconductor substrate 300. In some implementations, the isolation structure 334 may include a junction isolation structure in which impurities (e.g., P-type impurities) are implanted into the semiconductor substrate.

Each of the isolation structures (336a, 336b) may be formed as a sloped isolation structure that obliquely extends from the first surface of the semiconductor substrate 300 toward the second surface of the semiconductor substrate 300. For example, the isolation structure 336a may extend obliquely in a first diagonal direction from the pixel boundary region BR2 located on the first surface of the circuit region to the isolation structure 332 located on the second surface of the photoelectric conversion region 100 at one side of the control node 312 and the detection nodes (314a, 314b). In addition, the isolation structure 336b may extend obliquely in a second diagonal direction from the pixel boundary region BR2 located on the first surface of the circuit region 200 toward the isolation structure 322 located on the second surface of the photoelectric conversion region 100 at an opposite side of the control node 312 and the detection nodes (314a, 314b). In this case, the first diagonal direction and the second diagonal direction may be symmetrical to each other with respect to the pixel boundary region BR2.

The isolation structure 336a extending in the first diagonal direction and the isolation structure 336b extending in the second diagonal direction may be formed in a “V” shape in which one end portion of the isolation structure 336a and one end portion of the isolation structure 336b are in contact with each other in the pixel boundary region BR2 on the first surface.

As described above, since the isolation structures (336a, 336b) are formed in a “V” shape on both sides of the control node 312 and the detection nodes (314a, 314b), a region defined by the isolation structures (336a, 336b) under the control node 312 and the detection nodes (314a, 314b) may have a shape in which a width of the photoelectric conversion region 100 (i.e., a length in the second direction) gradually decreases in a direction from the first surface to the second surface. Accordingly, as shown in FIG. 5, electrons generated by the photoelectric conversion region 100 can be prevented from moving toward the circuit region 200, so that the electrons can be more easily focused toward the detection nodes (314a, 314b).

In addition, the isolation structures (336a, 336b) may prevent a current (e.g., a hole current) generated between adjacent control nodes 312 from flowing toward a ground node (VSS) of the circuit region 200, and may allow the hole current to flow only between the adjacent control nodes 312, thereby preventing power consumption and increasing directionality of the hole current. In addition, the isolation structures (336a, 336b) may prevent incident light received through the first surface of the semiconductor substrate 300 from being incident upon the circuit region 200, thereby preventing the operation of the pixel transistor (PX_Tr) from being affected by the incident light. The isolation structures (336a, 336b) may include a trench-shaped isolation structure formed such that an insulation material is buried in a trench formed by etching the semiconductor substrate 300 in a diagonal direction. For example, the isolation structures (336a, 336b) may include a Deep Trench Isolation (DTI) structure. Alternatively, the isolation structures (336a, 336b) may include a junction isolation structure in which impurities (e.g., P-type impurities) are implanted into the semiconductor substrate 300 in a diagonal direction.

An anti-reflection layer 340 may be formed on the first surface of the semiconductor substrate 300. The anti-reflection layer 340 may include silicon oxynitride (SiON) or silicon oxide (SiO₂). The anti-reflection layer 340 may also be used as a planarization layer.

A light blocking layer 350 may be formed over the anti-reflection layer 340 in the boundary regions (BR1, BR2) of the unit pixels. The light blocking layer 350 may include metal (e.g., tungsten).

A microlens 400 may be formed on the anti-reflection layer 340 and the light blocking layer 350 to converge incident light onto the photoelectric conversion region 100. The microlens 400 may be formed for each unit pixel.

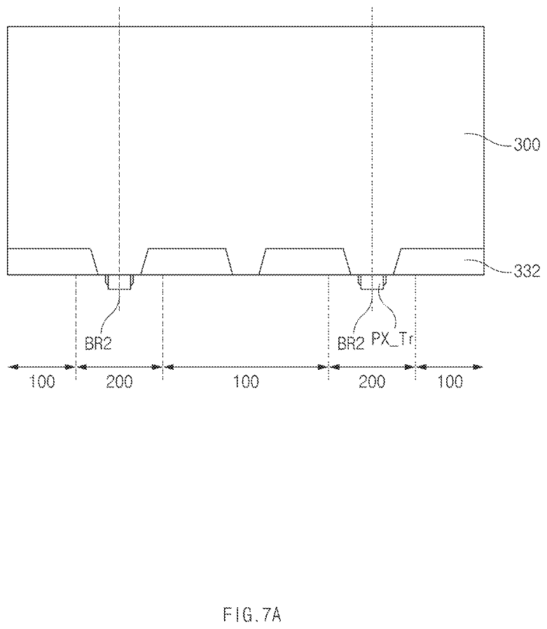

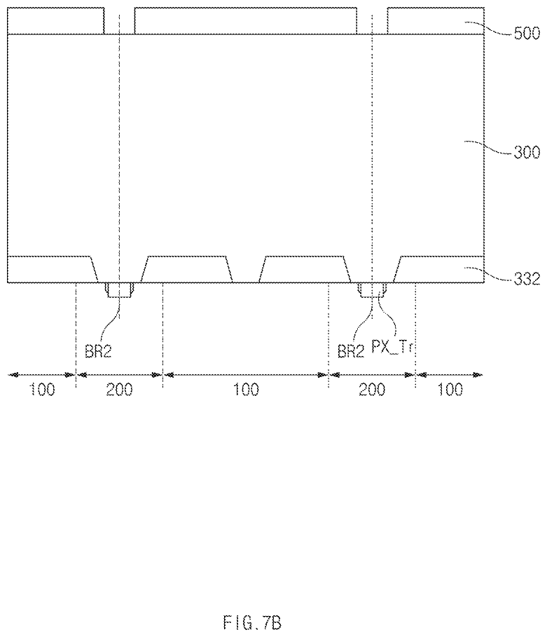

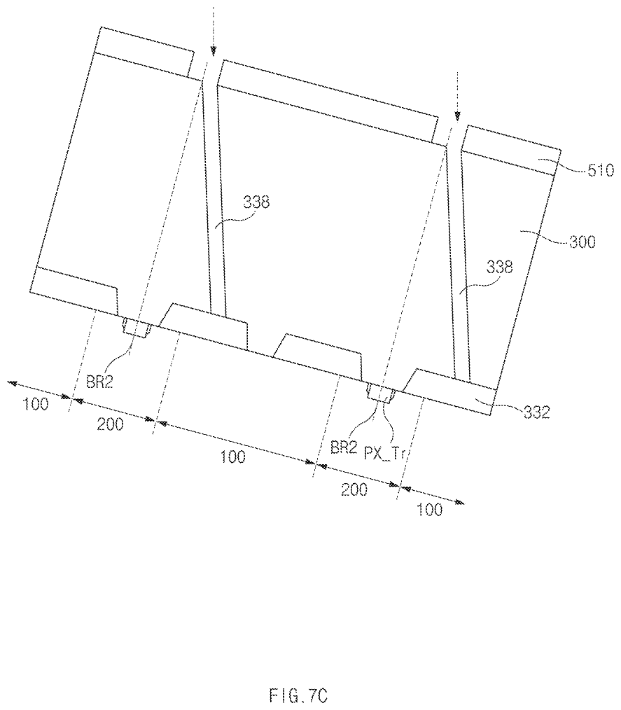

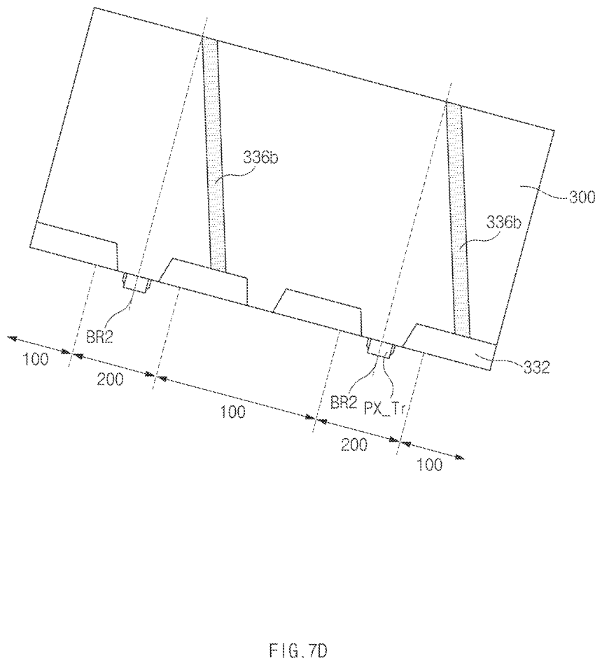

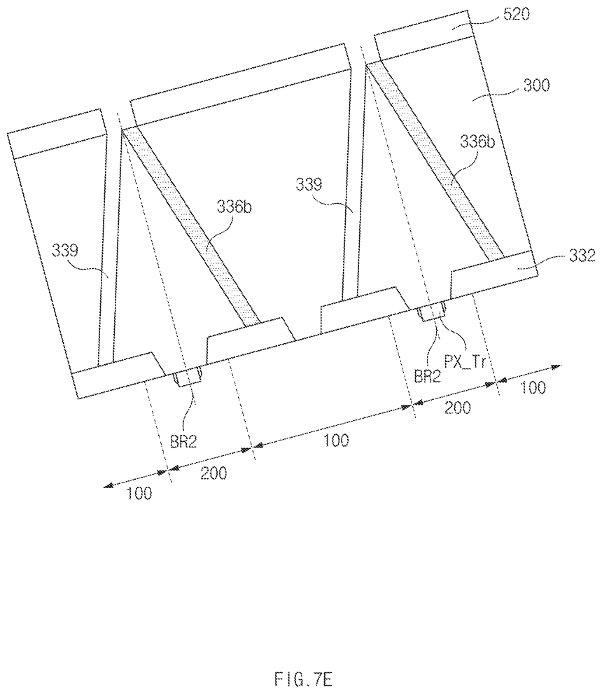

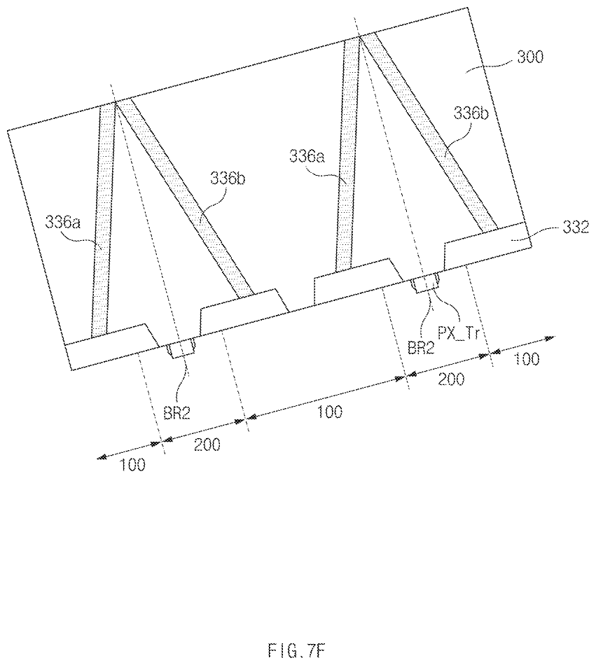

FIGS. 7A to 7F are cross-sectional views illustrating examples of a method for forming isolation structures shown in FIG. 5 based on some implementations of the disclosed technology.

First, referring to FIG. 7A, one or more isolation structures 332 may be formed on the second surface of the semiconductor substrate 300, and the pixel transistor (PX_Tr) may be formed in the circuit region 200.

For example, the second surface of the semiconductor substrate 300 may be etched to a predetermined depth to form a trench defining an active region in which the control node 312, the detection nodes (314a, 314b), and the pixel transistor (PX_Tr) are to be formed. Subsequently, the isolation structure 332 may be formed by filling the trench with an insulation material.

Then, the pixel transistor (PX_Tr) may be formed in some active regions formed in the circuit region 200 from among the active regions defined by the isolation structure 332.

Referring to FIG. 7B, a photoresist pattern 510 may be formed on the first surface of the semiconductor substrate 300 to expose the pixel boundary region BR2. In this case, the width of the region (e.g., an open region) exposed by the photoresist pattern 510 may be adjusted depending on the width of the isolation structures (336a, 336b) to be formed.

Referring to FIG. 7C, in a state in which the semiconductor substrate 300 on which the photoresist pattern 510 is formed is tilted to have a predetermined slope in a clockwise direction, the semiconductor substrate 300 may be etched until the isolation structure 332 is exposed using the photoresist pattern 510 as an etch mask, resulting in formation of a trench 338.

Referring to FIG. 7D, since the trench 338 is filled with insulation materials, the isolation structure (hereinafter referred to as a sloped isolation structure) 336b sloped in the first diagonal direction from among the isolation structures (336a, 336b) may be formed first.

Referring to FIG. 7E, a photoresist pattern 520 exposing the pixel boundary region BR2 may be formed on the first surface of the semiconductor substrate 300 again. The photoresist pattern 520 may be formed in the same shape as the photoresist pattern 510 shown in FIG. 7B.

Subsequently, in a state in which the semiconductor substrate 300 on which the photoresist pattern 520 is formed is tilted to have a predetermined slope in a counterclockwise direction, the semiconductor substrate 300 may be etched until the isolation structure 332 is exposed using the photoresist pattern 520 as an etch mask, resulting in formation of a trench 339.

Referring to FIG. 7F, since the trench 339 is filled with the insulation material, the sloped isolation structure 336a inclined in the second diagonal direction may be formed.

After all of the isolation structures (336a, 336b) are formed, the isolation structure 334 may be formed such that the isolation structures (336a, 336b) penetrate the isolation structure 334 in the second direction. Here, the isolation structure 334 may be formed using conventional DTI fabrication methods.

In an embodiment, the isolation structure 336a may be formed after the isolation structure 336b is formed. In another embodiment, the isolation structure 336b may be formed after the isolation structure 336a is formed.

In an embodiment, the isolation structure 336a and the isolation structure 336b may be separately formed through separate processes. In another embodiment, the isolation structure 336a and the isolation structure 336b may be formed together through a process. For example, after forming the trench 338 as shown in FIG. 7C, the trench 339 may first be formed as shown in FIG. 7E before filling the trench 338 with the insulation material. Subsequently, the trenches (338, 339) may be formed to be simultaneously filled with the insulation material after planarization of the semiconductor substrate 300, resulting in formation of the isolation structures (336a, 336b).

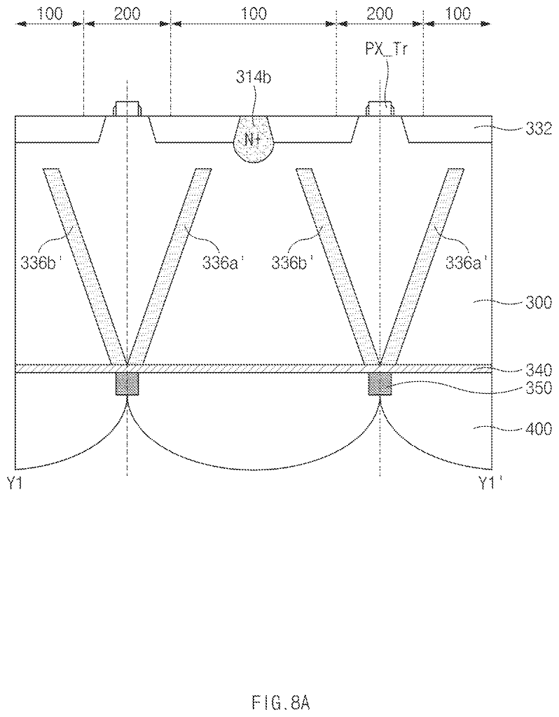

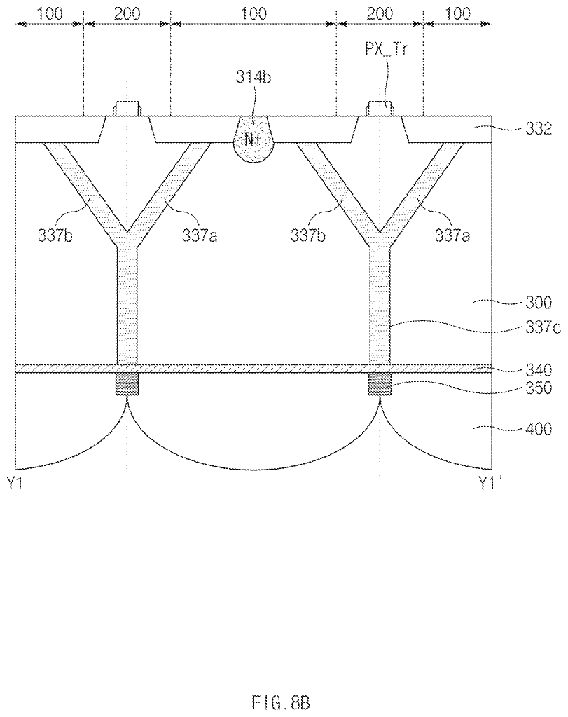

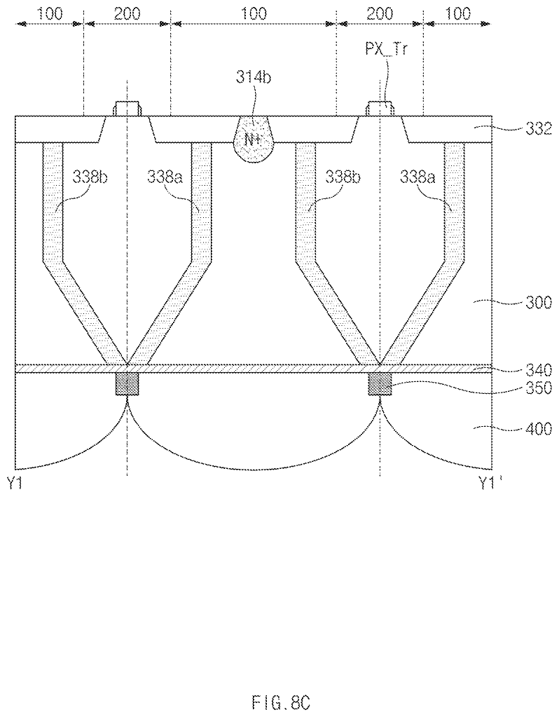

FIGS. 8A to 8C are cross-sectional views illustrating examples of the pixel array taken along the line Y1-Y1′ shown in FIG. 3 based on some implementations of the disclosed technology.

Referring to FIG. 8A, compared to the isolation structures (336a, 336b) of FIG. 5 described above, the isolation structures (336a′, 336b′) based on some embodiments may be formed to have a shorter length in the depth direction of the semiconductor substrate 300. For example, the isolation structures (336a′, 336b′) may be formed to have a length (depth) such that an end portion located close to the second surface of the semiconductor substrate 300 is not in contact with the isolation structure 332.

As described above, the length (depth) of each of the isolation structures (336a′, 336b′) is formed to be short, so that gapfill characteristics can be relatively improved when the trench is filled with the insulation material.

Referring to FIGS. 8B and 8C, a third isolation structure may be formed in a structure in which an obliquely extending portion is combined with a vertically extending portion.

For example, as shown in FIG. 8B, the isolation structures (337a, 337b, 337c) may be formed in a “Y” shape that includes not only the isolation structure 337c extending in a vertical direction from the first surface of the semiconductor substrate 300 toward the second surface of the semiconductor substrate 300 by a predetermined depth, but also the isolation structures (337a, 337b) that are connected to the end portion of the isolation structure 337c and obliquely extended in symmetrical diagonal directions from the isolation structure 337c toward the second surface of the semiconductor substrate 300.

In some implementations, as shown in FIG. 8C, each of the isolation structures (338a, 338b) may extend obliquely in a depth direction from the first surface of the semiconductor substrate 300 by a predetermined distance, and may then extend vertically toward the second surface of the semiconductor substrate. In this case, a first sloped portion in the isolation structure 338a and a second sloped portion in the isolation structure 338b may extend in diagonal directions symmetrical to each other, so that the first sloped portion and the second sloped portion are formed to be symmetrical to each other.

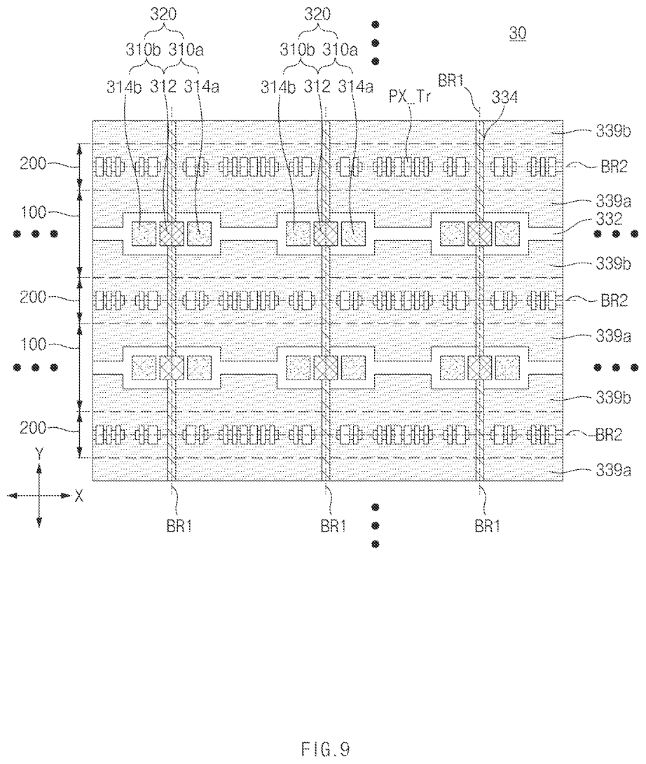

FIG. 9 is a plan view illustrating an example of the pixel array shown in FIG. 1 based on some implementations of the disclosed technology.

Referring to FIG. 9, in some embodiments, the isolation structures (339a, 339b) are partially different from the isolation structures (336a, 336b) of FIG. 3. The isolation structures (339a, 339b) may be formed such that the distance (i.e., the distance in the second direction) between the isolation structures (339a, 339b) can be changed depending on where the isolation structures (339a, 339b) are located within each unit pixel. For example, within each unit pixel region, the spacing between the isolation structures (339a, 339b) in the region between the taps 320 may be formed to be smaller than the spacing between the isolation structures (339a, 339b) located on both sides of the taps 320. Accordingly, the directionality of the current (e.g., a hole current) can be improved.

The isolation structures (339a, 339b) may be formed to be inclined in the depth direction of the semiconductor substrate 300 in the same manner as the isolation structures (336a, 336b) of FIG. 3.

In some embodiments, the sloped isolation structures are applied to the indirect TOF sensor. In other embodiments, the sloped isolation structures can also be applied to other depth sensors designed to capture signal carriers (electrons) generated in the substrate.

As is apparent from the above description, the image sensing device based on some implementations of the disclosed technology can improve detection efficiency while reducing power consumption required for a sensing operation.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
a substrate structured to extend in a first direction and a second direction perpendicular to the first direction and configured to include a first surface and a second surface opposite to the first surface;
a plurality of unit pixel regions supported by the substrate and configured to generate signal carriers through conversion of incident light;
a plurality of circuit structures supported by the substrate and arranged to be spaced apart from each other in the first direction and configured to generate a current in the substrate and capture the signal carriers carried by the current;
a first isolation structure disposed between adjacent unit pixel regions of the plurality of unit pixel regions in the substrate, and configured to extend vertically in a depth direction of the substrate while extending in the second direction; and
a plurality of second isolation structures located on two opposite sides of the plurality of circuit structures in the second direction within the substrate, and arranged to extend obliquely in a depth direction in the substrate while extending in the first direction.

2. The image sensing device according to claim 1, wherein the second isolation structures include:
a first sloped isolation structure extending obliquely from one side of the plurality of circuit structures in a first diagonal direction; and
a second sloped isolation structure extending obliquely from opposite sides of the plurality of circuit structures in a second diagonal direction symmetrical to the first diagonal direction.

3. The image sensing device according to claim 2, wherein:
the second isolation structures are arranged to be inclined such that a spacing between the first sloped isolation structure and the second sloped isolation structure tapers from the first surface toward the second surface.

4. The image sensing device according to claim 2, wherein each of the plurality of unit pixel regions in the substrate includes:
a photoelectric conversion region including the plurality of circuit structures and configured to generate the signal carriers therein;
a first circuit region disposed in a first pixel boundary region on one side of the photoelectric conversion region, and including a plurality of first pixel transistors disposed on the second surface;
a second circuit region disposed in a second pixel boundary region on an opposite side of the photoelectric conversion region, and including a plurality of second pixel transistors disposed on the second surface.

5. The image sensing device according to claim 4, wherein:
the first circuit region is isolated from the photoelectric conversion region by the first sloped isolation structure; and
the second circuit region is isolated from the photoelectric conversion region by the second sloped isolation structure.

6. The image sensing device according to claim 4, wherein:
the first sloped isolation structure extends obliquely from the first pixel boundary region of the first surface toward the second surface of the photoelectric conversion region; and
the second sloped isolation structure extends obliquely from the second pixel boundary region of the first surface toward the second surface of the photoelectric conversion region.

7. The image sensing device according to claim 4, further comprising:
a third isolation structure connected to the second isolation structures and structured to isolate the plurality of circuit structures, the plurality of first pixel transistors, and the plurality of second pixel transistors from each other.

8. The image sensing device according to claim 4, wherein the second isolation structures include:
a third sloped isolation structure extending from the first pixel boundary region of the first surface in the second diagonal direction; and
a fourth sloped isolation structure extending from the second pixel boundary region of the first surface in the first diagonal direction.

9. The image sensing device according to claim 8, wherein:
the first sloped isolation structure and the third sloped isolation structure are located symmetrical to each other with respect to the first pixel boundary region; and
the second sloped isolation structure and the fourth sloped isolation structure are located symmetrical to each other with respect to the second pixel boundary region.

10. The image sensing device according to claim 8, wherein:
the first sloped isolation structure and the third sloped isolation structure are formed to cover the first circuit region to prevent incident light received through the first surface from flowing into the first pixel transistors; and
the second sloped isolation structure and the fourth sloped isolation structure are formed to cover the second circuit region to prevent incident light received through the first surface from flowing into the second pixel transistors.

11. The image sensing device according to claim 2, wherein:
the first sloped isolation structure includes a portion that extends from the first surface in the first diagonal direction by a predetermined distance and another portion that extends vertically toward the second surface; and
the second sloped isolation structure includes a portion that extends from the first surface in the second diagonal direction by a predetermined distance and another portion that extends vertically toward the second surface.

12. The image sensing device according to claim 11, wherein the second isolation structures include:
a third sloped isolation structure in contact with the first sloped isolation structure on the first surface, the third sloped isolation structure including a portion that extends a predetermined distance from the first surface in the second diagonal direction and another portion that extends vertically toward the second surface; and
a fourth sloped isolation structure in contact with the second sloped isolation structure on the first surface, fourth sloped isolation structure including a portion that extends a predetermined distance from the first surface in the first diagonal direction and another portion that extends vertically toward the second surface.

13. The image sensing device according to claim 2, wherein:
the first sloped isolation structure and the second sloped isolation structure extend in the first direction while uniformly maintaining a spacing between the first sloped isolation structure and the second sloped isolation structure within a unit pixel.

14. The image sensing device according to claim 2, wherein:
the first sloped isolation structure and the second sloped isolation structure extend in the first direction such that a spacing between the first sloped isolation structure and the second sloped isolation structure changes depending on where the first sloped isolation structure and the second sloped isolation structure are located within the unit pixel.

15. The image sensing device according to claim 1, wherein:
the first isolation structure extends vertically from the first surface toward the second surface to overlap the circuit structures.

16. An image sensing device comprising:
a substrate extending in a first direction and a second direction perpendicular to the first direction and including a first surface and a second surface opposite to the first surface;
a plurality of circuit structures arranged to be spaced apart from each other in the first direction on the second surface of the substrate, and configured to generate a current in the substrate and capture the signal carriers moving by the current;
first pixel transistors disposed at one side of the plurality of circuit structures in the second direction on the second surface of the substrate;
second pixel transistors disposed at opposite sides of the plurality of circuit structures in the second direction on the second surface of the substrate;
a first isolation structure disposed obliquely in a depth direction of the substrate within the substrate, and configured to cover the first pixel transistors to prevent incident light received through the first surface from flowing into the first pixel transistors; and
a second isolation structure disposed obliquely in the depth direction of the substrate within the substrate, and configured to cover the second pixel transistors to prevent incident light received through the first surface from flowing into the second pixel transistors.

17. The image sensing device according to claim 16, wherein the first isolation structure and the second isolation structure are formed such that:
a width of a photoelectric conversion region in which the signal carriers are formed through conversion of the incident light tapers from the first surface toward the second surface; and
a width of a circuit region located under the first and second pixel transistors tapers from the first surface toward the second surface.

18. The image sensing device according to claim 16, wherein each of the first isolation structure and the second isolation structure includes:
a first sloped isolation structure extending obliquely in a first diagonal direction from the first surface toward the second surface; and
a second sloped isolation structure in contact with the first sloped isolation structure on the first surface and extending obliquely in a second diagonal direction symmetrical to the first diagonal direction from the first surface toward the second surface.

19. The image sensing device according to claim 16, wherein each of the first isolation structure and the second isolation structure includes:
a first portion extending vertically from the first surface toward the second surface to a predetermined depth;
a second portion connected to an end portion of the first portion, and extending obliquely from the end portion toward the second surface in a first diagonal direction; and
a third portion connected to an end portion of the first portion, and extending from the end portion toward the second surface in a second diagonal direction symmetrical to the first diagonal direction.

20. The image sensing device according to claim 16, wherein each of the first isolation structure and the second isolation structure includes:
a first sloped isolation structure including a portion that extends from the first surface in a first diagonal direction by a predetermined distance and another portion that extends vertically toward the second surface; and
a second sloped isolation structure in contact with the first sloped isolation structure on the first surface, the second sloped isolation structure including a portion that extends to a predetermined distance from the first surface in a second diagonal direction symmetrical to the first diagonal direction and another portion that extends vertically toward the second surface.
